(19) United States
(12) Patent Application Publication
(10) Pub. No.: US 2014/0131810 A1
(43) Pub. Date: May 15, 2014

(54) SEMICONDUCTOR MEMORY DEVICE

(71) Applicant: Unisantis Electronics Singapore PTE. Ltd, (US)

(72) Inventors: FUJIO MASUOKA, TOKYO (JP); SHINTARO ARAI, TOKYO (JP)

(73) Assignee: UNISANTIS ELECTRONICS SINGAPORE PTE. LTD, SINGAPORE (SG)

(21) Appl. No.: 13/762,935

(22) Filed: Feb. 8, 2013

Related U.S. Application Data
(60) Provisional application No. 61/599,028, filed on Feb. 15, 2012.

(51) Int. Cl. H01L 27/11

(52) U.S. Cl. CPC H01L 27/1104
USPC 257/369

(57) ABSTRACT

To realize a small SRAM cell area in a loadless 4T-SRAM constituted using vertical-type transistor SGTs.

In a static memory cell constituted using four MOS transistors, the MOS transistors are SGTs formed on a SOI substrate in which the drains, gates, and sources are arranged in the vertical direction. The gates of access transistors are shared, as a word line, among a plurality of cells adjacent to one another in the horizontal direction. One contact for the word line is formed for each group of cells, thereby realizing a CMOS-type loadless 4T-SRAM with a very small memory cell area.

### TECHNICAL FIELD

The present invention relates to a semiconductor memory device, and more particularly relates to a semiconductor memory device including an SRAM (Static Random Access Memory).

### BACKGROUND ART

To enhance the degree of integration and performance of semiconductor devices, an SGT (Surrounding Gate Transistor) which is a vertical-type gate transistor having a gate formed on the sidewall of a pillar-shaped semiconductor, formed on the surface of a semiconductor substrate, so as to surround the pillar-shaped semiconductor layer has been proposed (for example, PTL 1: Japanese Unexamined Patent Application Publication No. 2-188966). Because the drain, gate, and source are arranged in the vertical direction in the SGT, the occupied area can be greatly reduced, compared with a known planar-type transistor.

To constitute an LSI (large-scale integrated circuit) using SGTs, it is essential to use an SRAM including a combination of SGTs as a cache memory therefor. In recent years, there has been a very strong demand for increasing the capacity of an SRAM mounted on an LSI. In the case where SGTs are used, it is essential to realize an SRAM with a small cell area.

PTL 2 (International Publication No. WO 2009/096466) discusses a loadless 4T-SRAM formed on a SOI substrate by using four SGTs. FIG. 1 is an equivalent circuit diagram of the loadless 4T-SRAM. Also, FIG. 21 is a plan view of, and FIG. 22 includes cross-sectional views of the loadless 4T-SRAM in PTL 2.

Using the equivalent circuit of the loadless 4T-SRAM illustrated in FIG. 1, the operation principle of the loadless 4T-SRAM will be discussed below. The loadless 4T-SRAM includes a total of four transistors, namely, two access transistors for accessing a memory, which is a PMOS, and two driver transistors for driving a memory, which is an NMOS.

Hereinafter, as an example of the operation of a memory cell in FIG. 1, the operation of maintaining data in the case where “L” data is stored in a storage node Qa1 and “H” data is stored in a storage node Qb1 will be described.

While data is being maintained, a word line WL1, and bit lines BL1 and BLB1 are all driven at “H” potential. The off leak current of the access transistors (Qp11 and Qp21) is set to be, for example, about ten times to a thousand times greater than the off leak current of the driver transistors. Thus, the “H” level of the storage node Qb1 is maintained by the off leak current flowing from the bit line BLB1 to the storage node Qb1 through the access transistor Qp21. In contrast, the “L” level of the storage node Qa1 is maintained to be stable by the driver transistor Qn11.

FIG. 21 is a layout diagram of a known SRAM memory cell. In the SRAM cell array, unit cell UCs illustrated in FIG. 21 are repeatedly arranged. FIG. 22(a) to (d) illustrate the cross-sectional structures taken at cut lines A-A′, B-B′, C-C′, and D-D′ of the layout diagram illustrated in FIG. 21.

Firstly, using FIGS. 21 and 22, the layout of the SRAM cell of a first embodiment of PTL 2 will be described.

Storage nodes (602a and 602b) are formed of silicon layers formed on an embedded oxide film layer 601. The silicon layers are constituted of N+ diffusion layer areas (604a and 604b) and P+ diffusion layer areas (603a and 603b) formed by implanting an impurity or the like. Qp16 and Qp26 denote access transistors, and Qn16 and Qn26 denote driver transistors. A contact 610a formed on the storage node 602a is connected by a node connection line Na6 to a contact 611b formed on a gate line extending from a gate electrode of the driver transistor Qn26. A contact 610b formed on the storage node 602b is connected by a node connection line Nb6 to a contact 611a formed on a gate line extending from a gate electrode of the driver transistor Qn16. A contact 606a formed on the top of the access transistor Qp16 is connected to a bit line BL6. A contact 606b formed on the top of the access transistor Qp26 is connected to a bit line BLB6. A contact 607 formed on a gate line extending from gate electrodes of the access transistors Qp16 and Qp26 is connected to a word line WL6. Also, contacts (608a and 608b) formed on the top of the driver transistors (Qn16 and Qn26) are both connected to a wiring layer Vss6, which is at a ground potential.

Next, using the cross-sectional views illustrated in FIG. 22, the structure of the SRAM cell of the first embodiment of PTL 2 will be described.

As illustrated in FIG. 22(a), the P+ source diffusion layers (603a and 603b) made of silicon layers, which are the storage nodes (602a and 602b), are formed on the embedded oxide film layer 601. Silicide layers (613a and 613b) are formed on the source diffusion layers. A pillar-shaped silicon layer 621a constituting the access transistor Qp16 is formed on the P+ source diffusion layer area 603a. A pillar-shaped silicon layer 621b constituting the access transistor Qp26 is formed on the P+ source diffusion layer area 603b. A gate insulating film 617 and a gate electrode 618 are formed around each of the pillar-shaped silicon layers. A P+ drain diffusion layer area 616 is formed on the top of each of the pillar-shaped silicon layers by implanting an impurity or the like, and a silicide layer 615 is formed on the surface of the drain diffusion layer area. The contact 606a formed on the access transistor Qp16 is connected to the bit line BL6. The contact 606b formed on the access transistor Qp26 is connected to the bit line BLB6. The contact 607 formed on a gate line 618a extending from the gates of the access transistors Qp16 and Qp26 is connected to the word line WL6.

As illustrated in FIG. 22(b), the N+ source diffusion layers (604a and 604b) made of silicon layers, which are the storage nodes (602a and 602b), are formed on the embedded oxide film layer 601. The silicide layers (613a and 613b) are formed on the source diffusion layers. The contact 611a formed on a gate line 618b extending from the gate electrode of the driver transistor Qn16 is connected through the node connection line Na6 to the contact 610b formed on the N+ source diffusion layer 604b.

As illustrated in FIG. 22(c), the N+ source diffusion layers (604a and 604b) made of silicon layers, which are the storage nodes, are formed on the embedded oxide film layer 601. The silicide layers (613a and 613b) are formed on the N+ source diffusion layers. A pillar-shaped silicon layer 622a constituting the driver transistor Qn16 is formed on the N+ source diffusion layer area 604a. A pillar-shaped silicon layer 622b constituting the driver transistor Qn26 is formed on the N+ source diffusion layer area 604b. The gate insulating film 617 and the gate electrode 618 are formed around each of the pillar-shaped silicon layers. An N+ drain diffusion layer area 614 is formed on the top of each of the pillar-shaped silicon layers by implanting an impurity or the like, and the silicide layer 615 is formed on the surface of the drain diffusion layer area. The contacts (608a and 608b) formed on the driver transistors (Qn16 and Qn26) are connected to the ground potential Vss6 through the wiring layer.

As illustrated in FIG. 22(d), the P+ source diffusion layer 603a and the N+ source diffusion layer 604a made of silicon layers, which are the storage nodes, are formed on the embedded oxide film layer 601. The silicide layer 613a is formed on the source diffusion layers. The P+ source diffusion layer 603a and the N+ source diffusion layer 604a are connected by the silicide layer 613a.

### SUMMARY OF INVENTION

### Technical Problem

In the 4T-SRAM cell illustrated in FIGS. 21 and 22, the word line contact formed on the gates between the access transistors gives rise to dead space in the vertical direction, and the SRAM cell may not be formed in an efficient manner.

The present invention has been made with regard to the above-described circumstances, and an object thereof is to realize a loadless 4T-SRAM cell using SGTs with a smaller cell area than in a loadless 4T-SRAM using SGTs proposed in the past.

### Solution to Problem

To solve the above-described problem, the present invention provides a semiconductor memory device including a plurality of static memory cells, each of which includes four MOS transistors arranged on an insulating film formed on a substrate,

wherein the four MOS transistors

function as a first and a second PMOS access transistors and a first and a second NMOS driver transistors, respectively, the first and second PMOS access transistors for supplying an electric charge in order to maintain data in a memory cell and accessing the memory, the first and second NMOS driver transistors for driving storage nodes in order to write and read data to and from the memory cell,

wherein, in the first and second PMOS access transistors,

a P-conductivity-type first diffusion layer, a first pillar-shaped semiconductor layer, and a P-conductivity-type second diffusion layer are arranged in a hierarchical manner in a vertical direction on the insulating film formed on the substrate, the first pillar-shaped semiconductor layer is arranged between the first diffusion layer formed at the bottom of the first pillar-shaped semiconductor layer and the second diffusion layer formed on the top of the first pillar-shaped semiconductor layer, and a gate insulating film and a gate are formed on a sidewall of the first pillar-shaped semiconductor layer,

and wherein, in the first and second NMOS driver transistors,

an N-conductivity-type third diffusion layer, a second pillar-shaped semiconductor layer, and an N-conductivity-type fourth diffusion layer are arranged in a hierarchical manner in the vertical direction on the insulating film formed on the substrate, the second pillar-shaped semiconductor layer is arranged between the third diffusion layer formed at the bottom of the second pillar-shaped semiconductor layer and the fourth diffusion layer formed on the top of the first pillar-shaped semiconductor layer, and a gate insulating film and a gate are formed on a sidewall of the second pillar-shaped semiconductor layer;

wherein the first PMOS access transistor and the first NMOS driver transistor are arranged adjacent to each other,

wherein the second PMOS access transistor and the second NMOS driver transistor are arranged adjacent to each other,

wherein the P-conductivity-type first diffusion layer formed at the bottom of the first PMOS access transistor and the N-conductivity-type third diffusion layer formed at the bottom of the first NMOS driver transistor, which function as a first storage node for maintaining data, are arranged on the insulating film,

wherein the first diffusion layer and the third diffusion layer functioning as the first storage node are connected to each other,

wherein the P-conductivity-type first diffusion layer formed at the bottom of the second PMOS access transistor and the N-conductivity-type third diffusion layer formed at the bottom of the second NMOS driver transistor, which function as a second storage node for maintaining data, are arranged on the insulating film,

wherein the first diffusion layer and the third diffusion layer functioning as the second storage node are connected to each other,

wherein gates of the first and second PMOS driver transistors are connected to each other by a first gate line, and the first gate line forms a word line by connecting to gates of the first and second PMOS access transistors in a plurality of memory cells adjacent to one another, and

wherein, for each group of memory cells adjacent to one another, a first contact is formed on the first gate line serving as the word line.

In a preferred aspect, there is provided a semiconductor memory device wherein, as in a memory cell, pillars are arranged in an area in which the first contact is formed on the first gate line serving as the word line.

In another preferred aspect, there is provided a semiconductor memory device wherein a second gate line extending from the gate of the first NMOS driver transistor is connected to the diffusion layers functioning as the second storage node by a second contact, and a third gate line extending from the gate of the second NMOS driver transistor is connected to the diffusion layers functioning as the first storage node by a third contact.

In yet another preferred aspect, there is provided a semiconductor memory device wherein a peripheral length of sidewalls of the pillar-shaped semiconductor layers forming the first and second NMOS driver transistors is longer than or equal to a peripheral length of sidewalls of the pillar-shaped semiconductor layers forming the first and second PMOS access transistors, or the peripheral length of the sidewalls of the pillar-shaped semiconductor layers forming the first and second NMOS driver transistors is shorter than or equal to the peripheral length of the sidewalls of the pillar-shaped semiconductor layers forming the first and second PMOS access transistors.

In yet another preferred aspect, there is provided a semiconductor memory device wherein the four MOS transistors are arranged in two rows and two columns on the insulating film, the first PMOS access transistor is arranged at a first column of a first row, the first NMOS driver transistor is arranged at a first column of a second row, the second PMOS access transistor is arranged at a second column of the first row, and the second NMOS driver transistor is arranged at a second column of the second row.

In yet another preferred aspect, there is provided a semiconductor memory device wherein the four MOS transistors are arranged on the insulating film; the first PMOS access transistor and the second PMOS access transistor are arranged adjacent to each other; in one direction orthogonal to a direction in which the first PMOS access transistor and the second PMOS access transistor are arranged adjacent to each other, the first NMOS driver transistor is arranged adjacent to the first PMOS access transistor; and, in the other direction orthogonal to the direction in which the first PMOS access transistor and the second PMOS access transistor are arranged adjacent to each other, the second NMOS driver transistor is arranged adjacent to the second PMOS access transistor.

### BRIEF DESCRIPTION OF DRAWINGS

FIG. 1 is an equivalent circuit illustrating an SRAM of the present invention.

FIG. 2 is a plan view of an SRAM indicating a first embodiment of the present invention.

FIG. 3 includes plan views of the SRAM indicating the first embodiment of the present invention.

FIG. 4(a) is a cross-sectional view of the SRAM indicating the first embodiment of the present invention.

FIG. 4(b) is a cross-sectional view of the SRAM indicating the first embodiment of the present invention.

FIG. 4(c) is a cross-sectional view of the SRAM indicating the first embodiment of the present invention.

FIG. 4(d) is a cross-sectional view of the SRAM indicating the first embodiment of the present invention.

FIG. 4(e) is a cross-sectional view of the SRAM indicating the first embodiment of the present invention.

FIG. 5 includes process charts illustrating a fabrication method of the present invention in the order of processes.

FIG. 6 includes process charts illustrating the fabrication method of the present invention in the order of processes.

FIG. 7 includes process charts illustrating the fabrication method of the present invention in the order of processes.

FIG. 8 includes process charts illustrating the fabrication method of the present invention in the order of processes.

FIG. 9 includes process charts illustrating the fabrication method of the present invention in the order of processes.

FIG. 10 includes process charts illustrating the fabrication method of the present invention in the order of processes.

FIG. 11 includes process charts illustrating the fabrication method of the present invention in the order of processes.

FIG. 12 includes process charts illustrating the fabrication method of the present invention in the order of processes.

FIG. 13 includes process charts illustrating the fabrication method of the present invention in the order of processes.

FIG. 14 includes process charts illustrating the fabrication method of the present invention in the order of processes.

FIG. 15 includes process charts illustrating the fabrication method of the present invention in the order of processes.

FIG. 16 is a plan view of an SRAM indicating a second embodiment of the present invention.

FIG. 17 is a plan view of an SRAM indicating a third embodiment of the present invention.

FIG. 18 is a plan view of an SRAM indicating a fourth embodiment of the present invention.

FIG. 19 is a plan view of an SRAM indicating a fifth embodiment of the present invention.

FIG. 20 includes plan views of the SRAM indicating the fifth embodiment of the present invention.

FIG. 21 is a plan view of an SRAM using known SGTs.

FIG. 22(a) is a cross-sectional view of the SRAM using the known SGTs.

FIG. 22(b) is a cross-sectional view of the SRAM using the known SGTs.

FIG. 22(c) is a cross-sectional view of the SRAM using the known SGTs.

FIG. 22(d) is a cross-sectional view of the SRAM using the known SGTs.

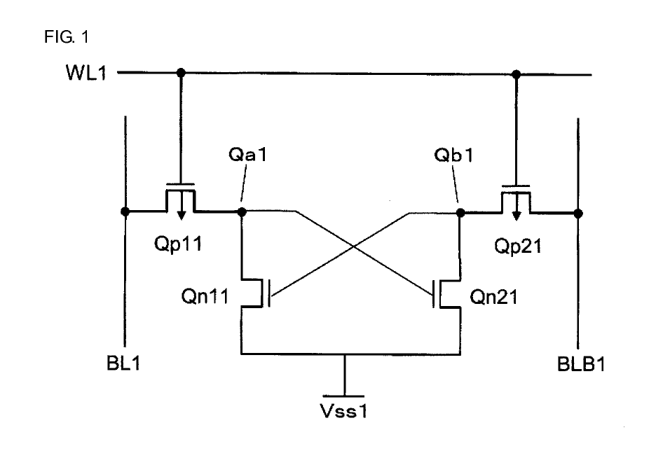

### DESCRIPTION OF EMBODIMENTS

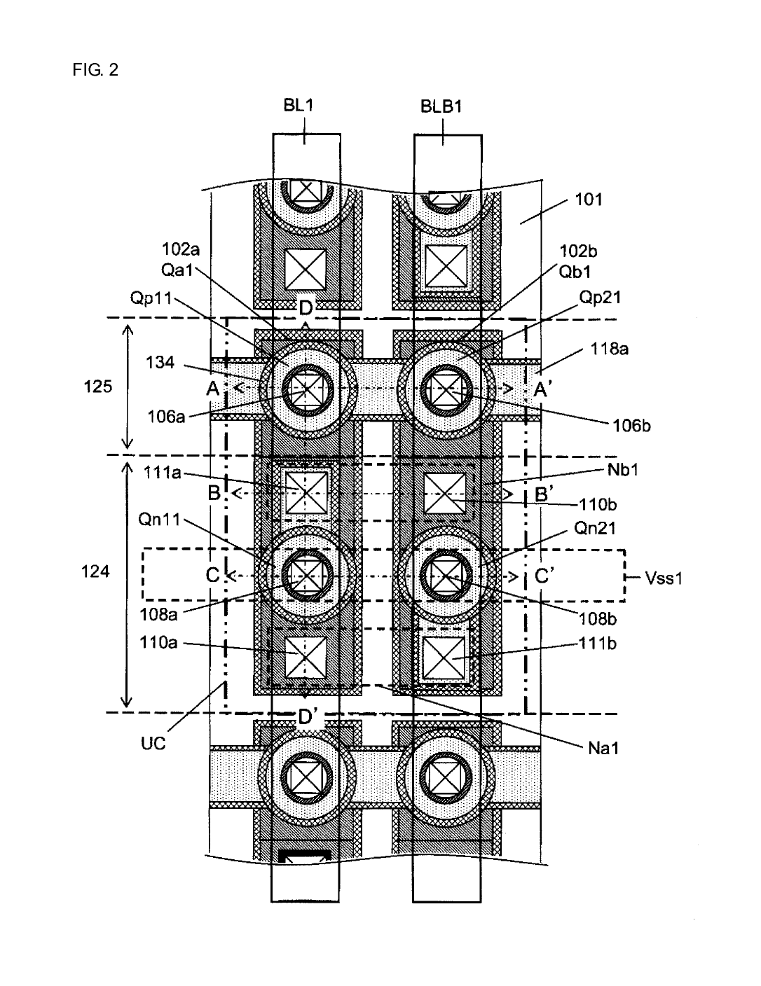

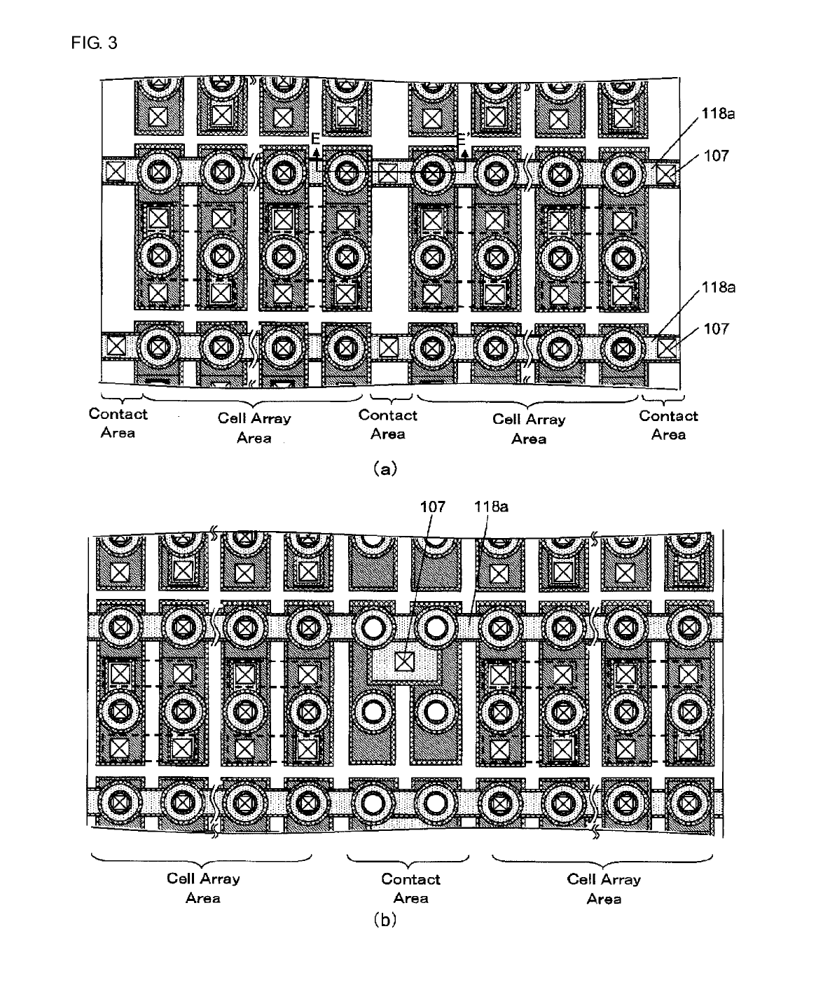

FIG. 2 is a layout diagram of an SRAM memory cell according to a first embodiment of the present invention. In the SRAM memory cell array, unit cell UCs illustrated in FIG. 2 are repeatedly arranged. FIG. 3(a) to (d) illustrate the cross-sectional structures taken at cut lines A-A′, B-B′, C-C′, and D-D′ of the layout diagram illustrated in FIG. 2.

### First Embodiment

Firstly, with reference to the layout diagram illustrated in FIG. 2, this embodiment will be described.

Qp11 and Qp21 are access transistors for accessing a memory cell, which is a PMOS. Qn11 and Qn21 are driver transistors for driving a memory cell, which is an NMOS.

In this embodiment, one unit cell UC has transistors arranged in two rows and two columns on the substrate. At the first column, from the top of the diagram, the access transistor Qp11 and the driver transistor Qn11 are arranged on the first storage node Qa1. Also, at the second column, from the top of the diagram, the access transistor Qp21 and the driver transistor Qn21 are arranged on the second storage node Qb1. Also, a gate line 134 extending from the gates of the access transistors is shared among a plurality of memory cells adjacent to one another in the horizontal direction, thereby forming a word line. The SRAM cell array of this embodiment is constituted by consecutively arranging unit cells UCs, each having four such transistors, in the vertical direction of the diagram.

Storage nodes (102a and 102b) are formed of silicon layers formed on an embedded oxide film layer 101. The silicon layers are constituted of N+ diffusion layer areas (104a and 104b) and P+ diffusion layer areas (103a and 103b) formed by implanting an impurity or the like. Qp11 and Qp21 denote access transistors, and Qn11 and Qn21 denote driver transistors. A contact 110a formed on the storage node 102a is connected by a node connection line Na1 to a contact 111b formed on a gate line extending from a gate electrode of the driver transistor Qn21. A contact 110b formed on the storage node 102b is connected by a node connection line Nb1 to a contact 111a formed on a gate line extending from a gate electrode of the driver transistor Qn11. Contacts (108a and 108b) formed on the top of the driver transistors (Qn11 and Qn21) are both connected to a wiring layer Vss1, which is at a ground potential. A contact 106a formed on the top of the access transistor Qp11 is connected to a bit line BL1. A contact 106b formed on the top of the access transistor Qp21 is connected to a bit line BLB1. A gate line (118a) extending from the gate electrodes of the access transistors Qp11 and Qp21 is connected, as a word line, to a plurality of memory cells adjacent to one another in the horizontal direction.

As an example of the configuration of the hierarchical wiring, it is possible to realize a configuration in which the node connection line Na1, the node connection line Nb1, and the ground potential line Vss1 are formed of lower layer lines, and the bit lines (BL1 and BLB1) are formed of upper layer lines.

FIG. 3(a) is a plan view of a portion of the SRAM memory cell array including a plurality of SRAM memory cells.

In a cell array area in the diagram, a plurality of memory cells is arranged in the horizontal direction, and the word line 118a is shared among the plurality of memory cells arranged in the horizontal direction. The word line is connected to wiring at an upper layer by a contact 107 formed in a contact area and, as necessary, backed by a wiring layer. Therefore, unlike the SRAM cells in PTL 2, it is unnecessary to form, in each cell, a contact for the word line. Thus, the SRAM cell area can be reduced.

By connecting a plurality of cells to the word line 118a, there may be a problem of reading or writing delay due to delay of a signal on the word line at a cell distant from the word line contact 107. Therefore, the number of cells connected to the word line may be determined, on the basis of the design specification of each device or the like, within the range where there is no problem of reading or writing delay.

FIG. 3(b) is a plan view of a portion of the SRAM cell array including a plurality of SRAM cells in another case. Similarly, in a cell array area in the diagram, a plurality of memory cells is arranged in the horizontal direction, and the word line 118a is shared among the plurality of memory cells arranged in the horizontal direction. However, in FIG. 3(b), as in the cell array area, pillars are arranged also in a contact area. By arranging pillars also in the contact area in the same pattern as that in the memory cell area, the regularity of the same pillar arrangement as in the cell array can be maintained also in the contact area. Thus, the difference in size between a pillar adjacent to the contact area and a pillar not adjacent to the contact area can be reduced, and errors between characteristics of SGTs adjacent to the contact area and characteristics of SGTs not adjacent to the contact area can be suppressed to the minimum.

In FIG. 3, the configuration of the word line and the word line contact has been described using the layout of the first embodiment by way of example. In fact, this is not limited to the layout of the first embodiment, and the same or similar configuration of the word line and the word line contact is applicable to layouts of other embodiments.

In the present invention, the source and drain of each of the transistors constituting the SRAM are defined as follows. Regarding the driver transistors (Qn11 and Qn21), a diffusion layer formed on the top of a pillar-shaped semiconductor layer connected to the ground voltage is defined as a source diffusion layer, and a diffusion layer formed at the bottom of the pillar-shaped semiconductor layer is defined as a drain diffusion layer. Regarding the access transistors (Qp11 and Qp21), depending on the operation state, a diffusion layer formed on the top of and a diffusion layer formed at the bottom of the pillar-shaped semiconductor layer may both become the sources or drains; to simplify the description, the diffusion layer formed on the top of the pillar-shaped semiconductor layer is defined as a source diffusion layer, and the diffusion layer formed at the bottom of the pillar-shaped semiconductor layer is defined as a drain diffusion layer.

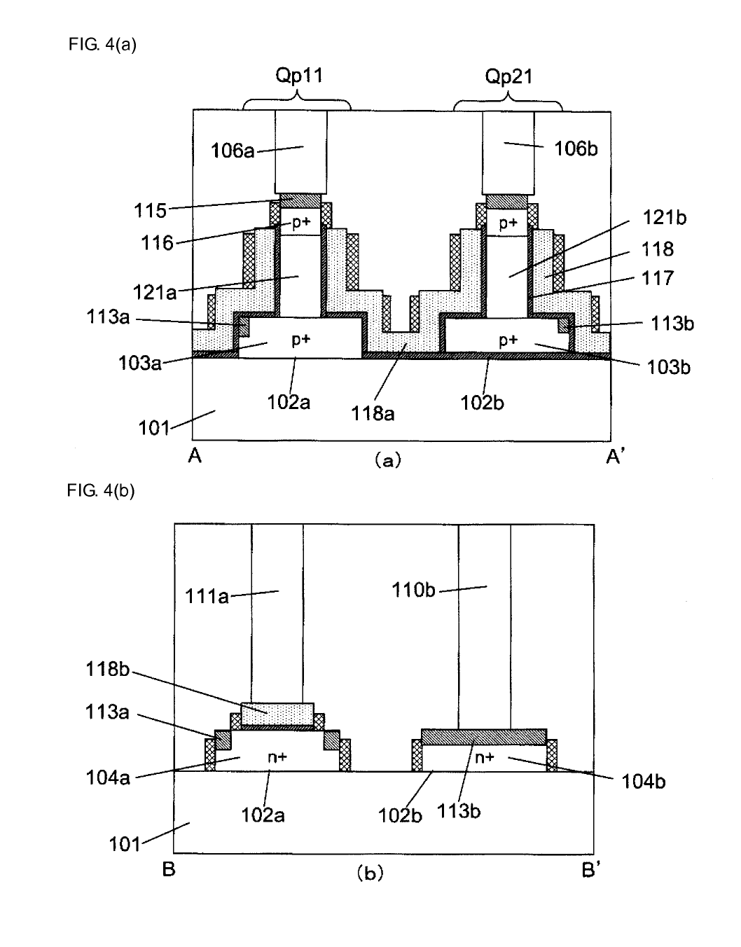

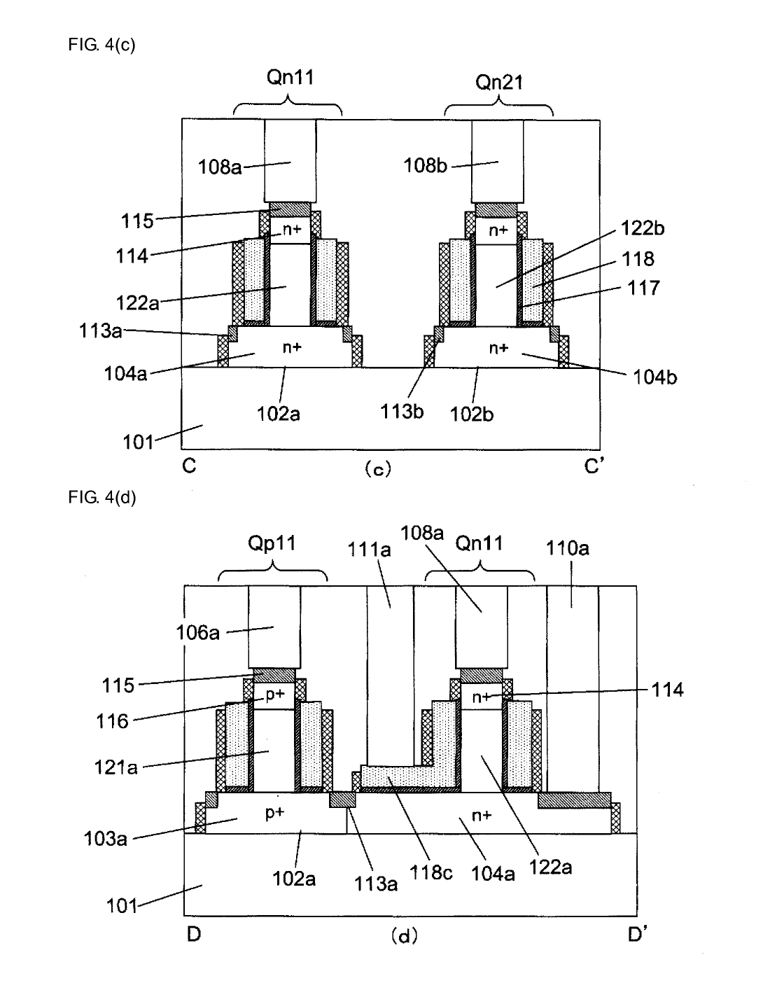

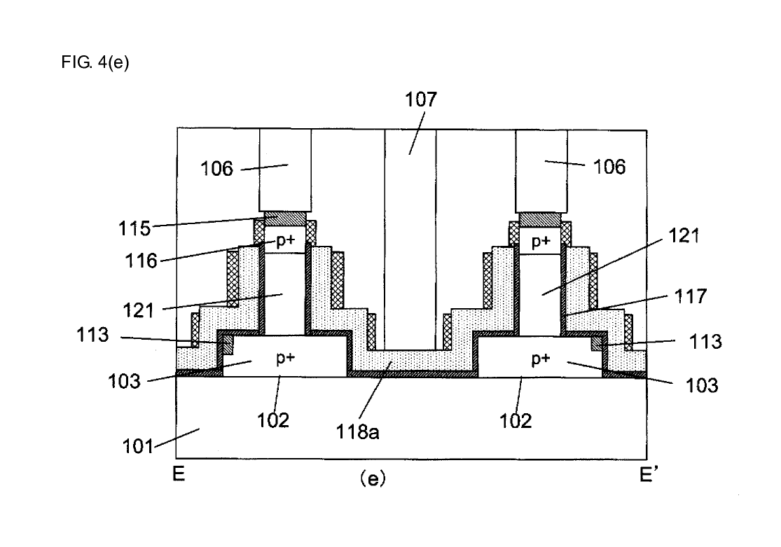

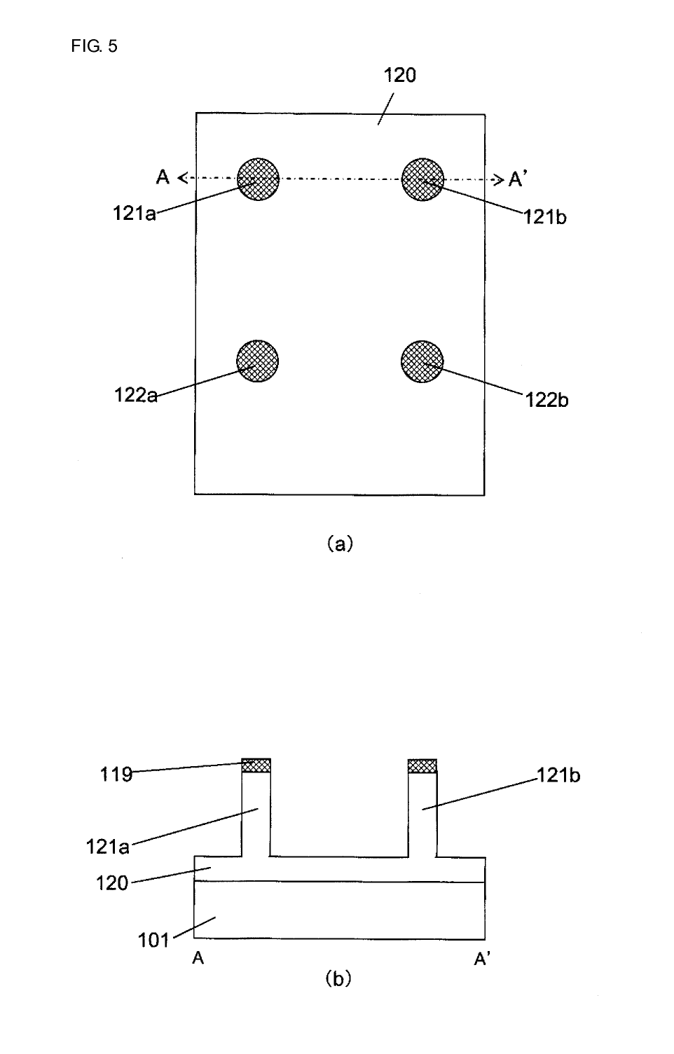

Next, the present invention will be described with reference to the cross-sectional structures in FIG. 4.

As illustrated in FIG. 4(a), the P+ source diffusion layers (103a and 103b) made of silicon layers, which are the storage nodes (102a and 102b), are formed on the embedded oxide film layer 101. Silicide layers (113a and 113b) are formed on the source diffusion layers. A pillar-shaped silicon layer 121a constituting the access transistor Qp11 is formed on the P+ source diffusion layer 103a. A pillar shaped silicon layer 121b constituting the access transistor Qp21 is formed on the P+ source diffusion layer 103b. A gate insulating film 117 and a gate electrode 118 are formed around each of the pillar-shaped silicon layers. A P+ drain diffusion layer area 116 is formed on the top of each of the pillar-shaped silicon layers by implanting an impurity or the like, and a silicide layer 115 is formed on the surface of the drain diffusion layer area. The contact 106a formed on the access transistor Qp11 is connected to the bit line BL1. The contact 106b formed on the access transistor Qp21 is connected to the bit line BLB1.

As illustrated in FIG. 4(b), the N+ source diffusion layers (104a and 104b) made of silicon layers, which are the storage nodes (102a and 102b), are formed on the embedded oxide film layer 101. The silicide layers (113a and 113b) are formed on the source diffusion layers. The contact 111a formed on a gate line 118b extending from the gate electrode of the driver transistor Qn11 is connected through the node connection line Na to the contact 110b formed on the N+ source diffusion layer 104b.

As illustrated in FIG. 4(c), the N+ source diffusion layers (104a and 104b) made of silicon layers, which are the storage nodes, are formed on the embedded oxide film layer 101. The silicide layers (113a and 113b) are formed on the N+ source diffusion layers. A pillar-shaped silicon layer 122a constituting the driver transistor Qn11 is formed on the N+ source diffusion layer 104a. A pillar-shaped silicon layer 122b constituting the driver transistor Qn21 is formed on the N+ source diffusion layer 104b. The gate insulating film 117 and the gate electrode 118 are formed around each of the pillar-shaped silicon layers. An N+ drain diffusion layer area 114 is formed on the top of each of the pillar-shaped silicon layers by implanting an impurity or the like, and the silicide layer 115 is formed on the surface of the drain diffusion layer area. The contacts (108a and 108b) formed on the driver transistors (Qn11 and Qn21) are both connected to the ground potential Vss1 through the wiring layer.

As illustrated in FIG. 4(d), the P+ source diffusion layer 103a and the N+ source diffusion layer 104a made of silicon layers, which are the storage nodes, are formed on the embedded oxide film layer 101. The silicide layer 113a is formed on the source diffusion layers. The P+ source diffusion layer 103a and the N+ source diffusion layer 104a are connected by the silicide layer 113a.

In this embodiment, an N+ source diffusion layer and a P+ source diffusion layer are connected by silicide. When the contact resistance between the N+ source diffusion layer and the P+ source diffusion layer is sufficiently small, it is unnecessary to form silicide. Alternatively, instead of connecting the N+ source diffusion layer and the P+ source diffusion layer by silicide, connection may be made by backing the N+ source diffusion layer and the P+ source diffusion layer with a contact, or the N+ source diffusion layer and the P+ source diffusion layer may be connected by another method.

FIG. 4(e) is the cross-sectional structure taken at line E-E′ in FIG. 3(a).

On the embedded oxide film layer 101, P+ source diffusion layers 103 made of a silicon layer of cells on the left side and cells on the right side are formed. A silicide layer 113 is formed on each of the source diffusion layers. A pillar-shaped silicon layer 121 forming an access transistor is formed on each of the P+ source diffusion layer areas 103. A pillar-shaped silicon layer 121 forming an access transistor is formed on each of the P+ source diffusion layer areas 103. The gate insulating film 117 and the gate electrode 118 are formed around each of the pillar-shaped silicon layers. The P+ drain diffusion layer area 116 is formed on the top of each of the pillar-shaped silicon layers by implanting an impurity or the like. The silicide layer 115 is formed on the surface of each of the drain diffusion layer areas. A contact 106 formed on each of the access transistors is connected to a bit line, and the contact 107 formed on the word line 118a is connected to a word line with a lower resistance than that formed of a wiring layer at an upper layer.

Hereinafter, an example of a fabrication method for forming the semiconductor device of the present invention will be described with reference to FIGS. 5 to 13. In each diagram, (a) is a plan view, and (b) is a cross-sectional view taken at D-D′.

As illustrated in FIG. 5, a silicon nitride film or the like is formed on a SOI substrate. A pattern including pillar-shaped silicon layers (121a, 122a, 121b, and 122b) is formed by lithography and is etched, thereby forming a silicon nitride film mask 119 and pillar-shaped silicon layers (121a, 122a, 121b, and 122b).

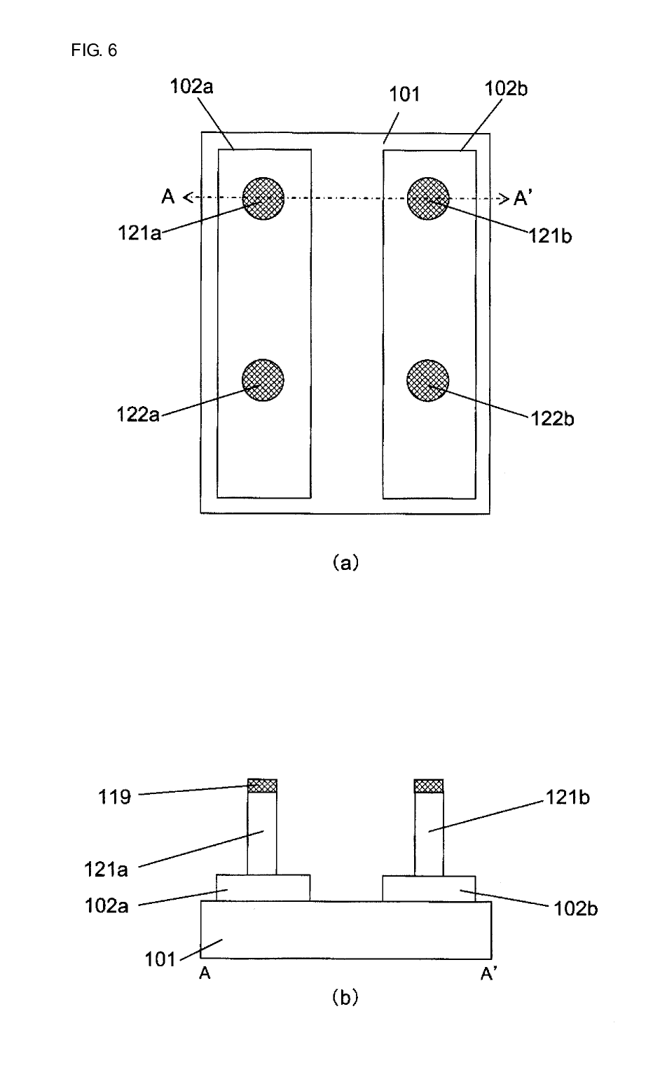

As illustrated in FIG. 6, a silicon layer (120) is separated to form silicon layers that are storage nodes (102a and 102b).

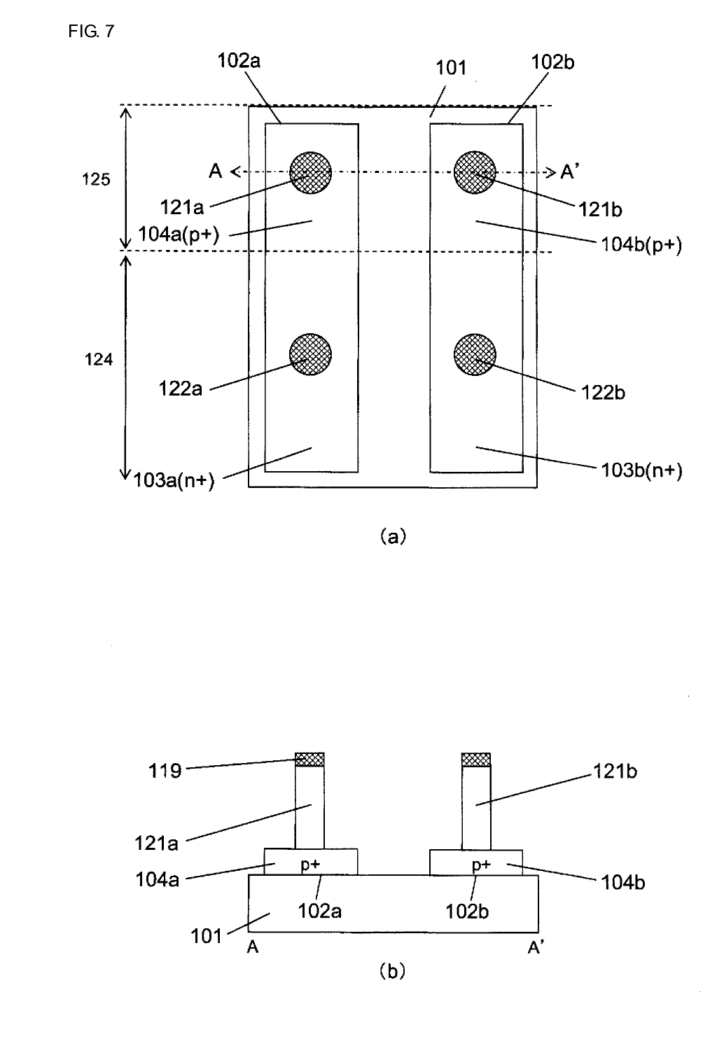

As illustrated in FIG. 7, an impurity is introduced into a P+ implanting area 124 and an N+ implanting area 125 by performing ion implantation or the like, and drain diffusion layers (103a, 103b, 104a, and 104b) are formed at the bottom of the pillar-shaped silicon layers on the substrate.

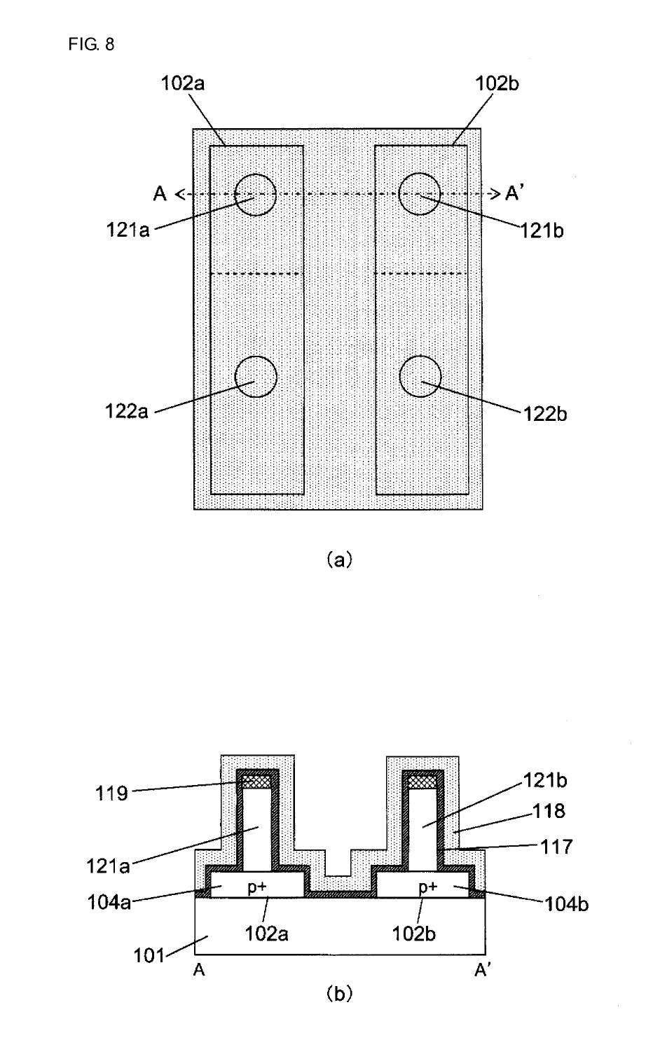

As illustrated in FIG. 8, a gate insulating film 117 and a gate conducting film 118 are formed. The gate insulating film 117 is formed of an oxide film or a high-k film. Also, the gate conducting film is formed of polysilicon or a metal film.

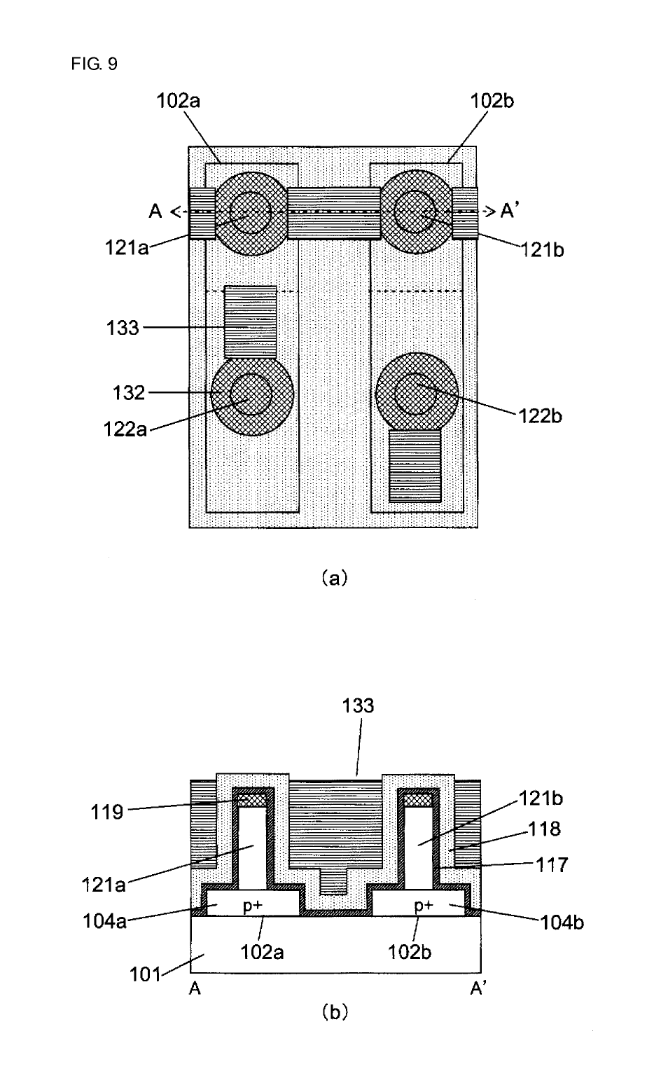

As illustrated in FIG. 9, a gate wiring pattern is formed by lithography using a resist or the like 133.

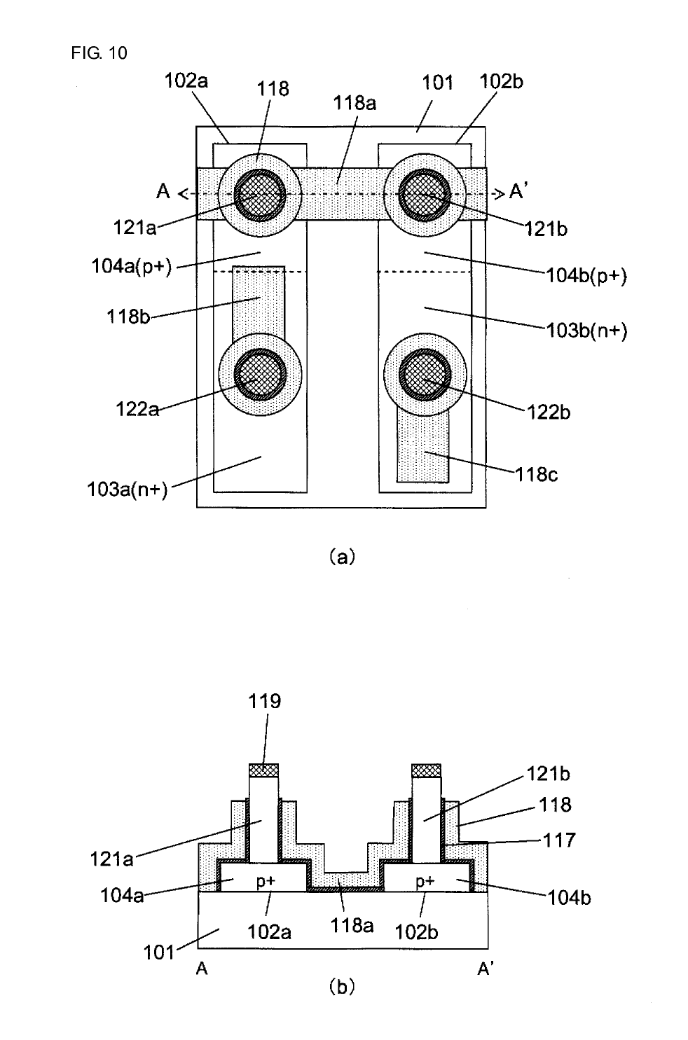

As illustrated in FIG. 10, the gate conducting film 117 and the gate insulating film 118 are etched and removed by using the resist 133 as a mask. Accordingly, gate lines (118a to 118c) are formed.

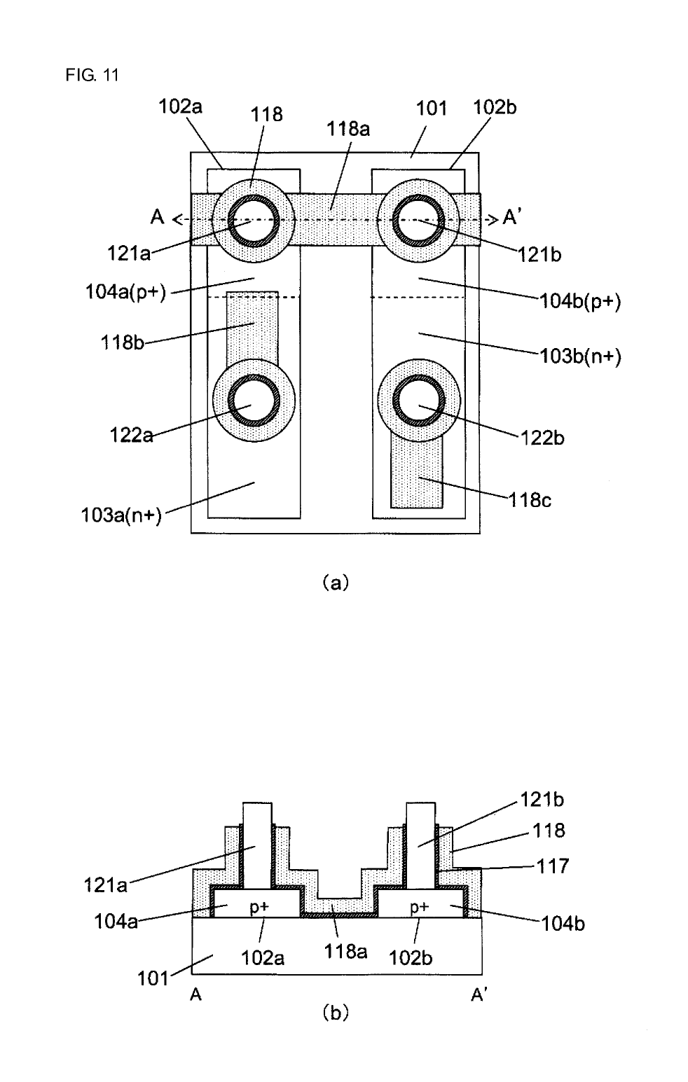

As illustrated in FIG. 11, the mask 119 on the pillars is removed by performing wet etching, dry etching, or the like.

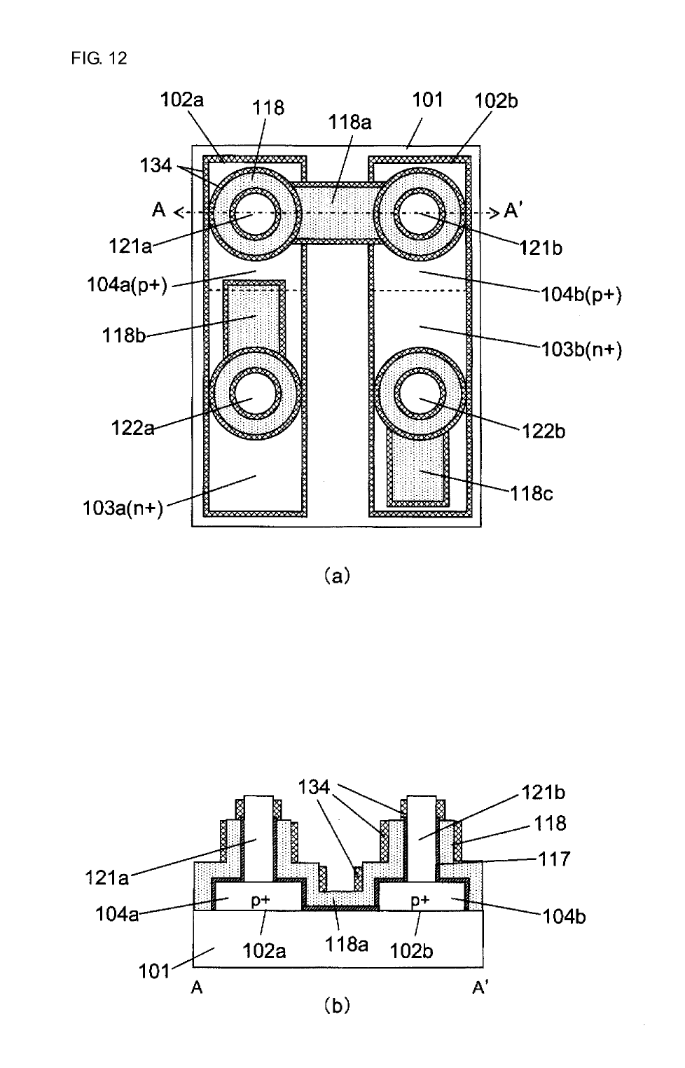

As illustrated in FIG. 12, after an insulating film such as a silicon nitride film is formed, etch back is performed to obtain a structure in which an insulating film 134 such as a silicon nitride film covers the sidewalls of the pillar-shaped silicon layers and the sidewall of a gate electrode.

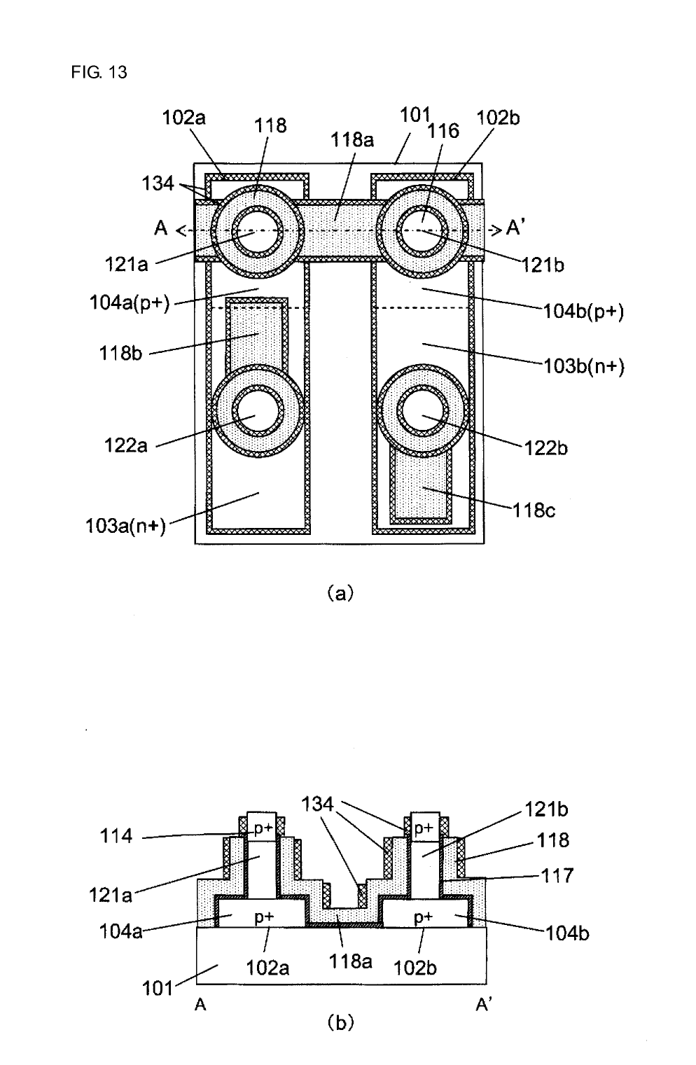

As illustrated in FIG. 13, source diffusion layers (114 and 116) on the top of the pillar-shaped silicon layers are formed by introducing an impurity into the P+ implanting area 124 and the N+ implanting area 125 by performing ion implantation or the like.

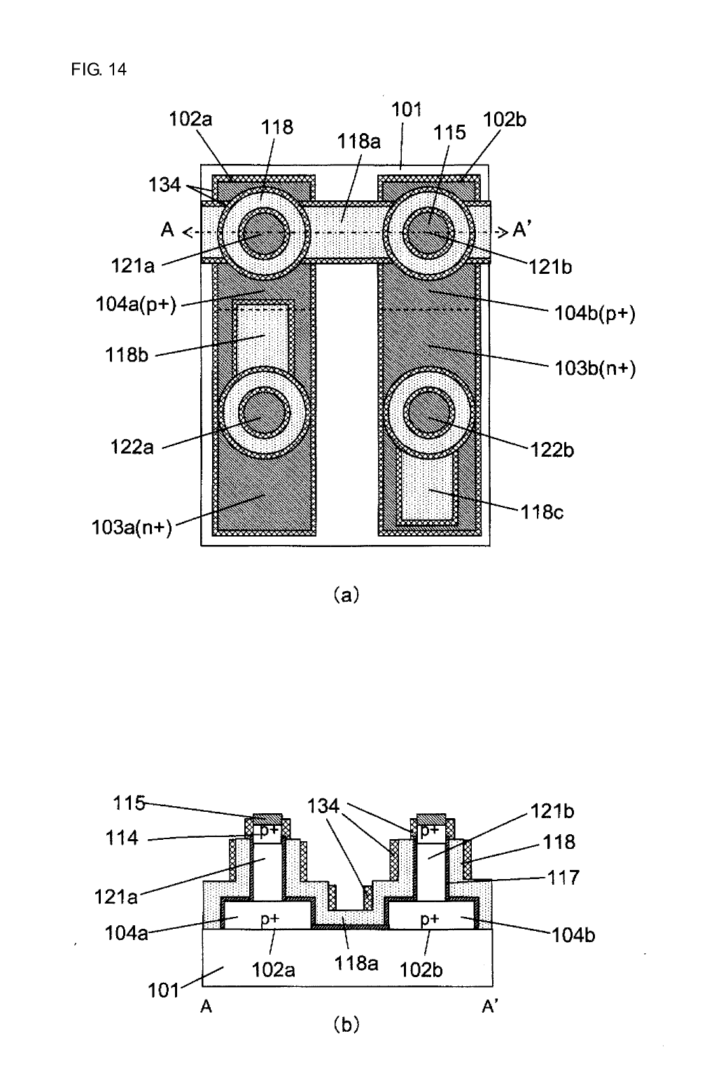

As illustrated in FIG. 14, metal such as Ni is sputtered and subjected to heat treatment, thereby forming silicide layers (113a and 113b) on the drain diffusion layers and a silicide layer 115 on the source diffusion layers on the top of the pillar-shaped silicon layers.

Here, short circuit between the drain and the gate and between the source and the gate, resulting from the silicide layers, can be suppressed by the insulating film 134 such as a silicon nitride film covering the sidewalls of the pillar-shaped silicon layers and of the gate electrode.

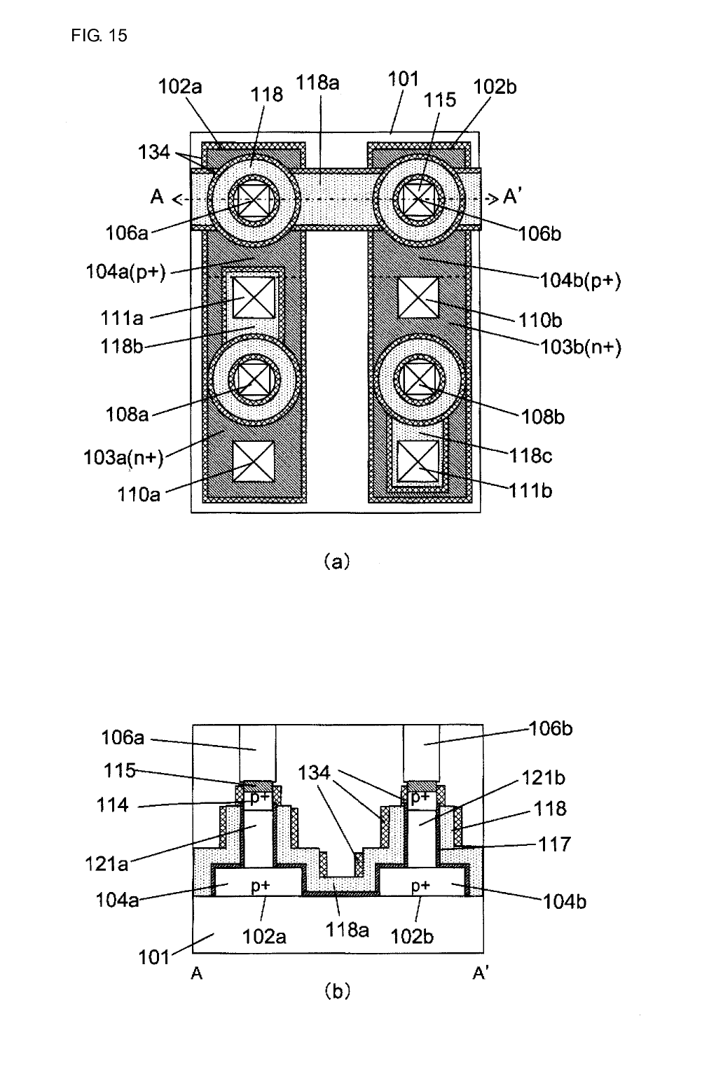

As illustrated in FIG. 15, after a silicon oxide film which is an interlayer film is formed, contacts (106a, 106b, 108a, 108b, 110a, 110b, 111a, and 111b) are formed.

### Second Embodiment

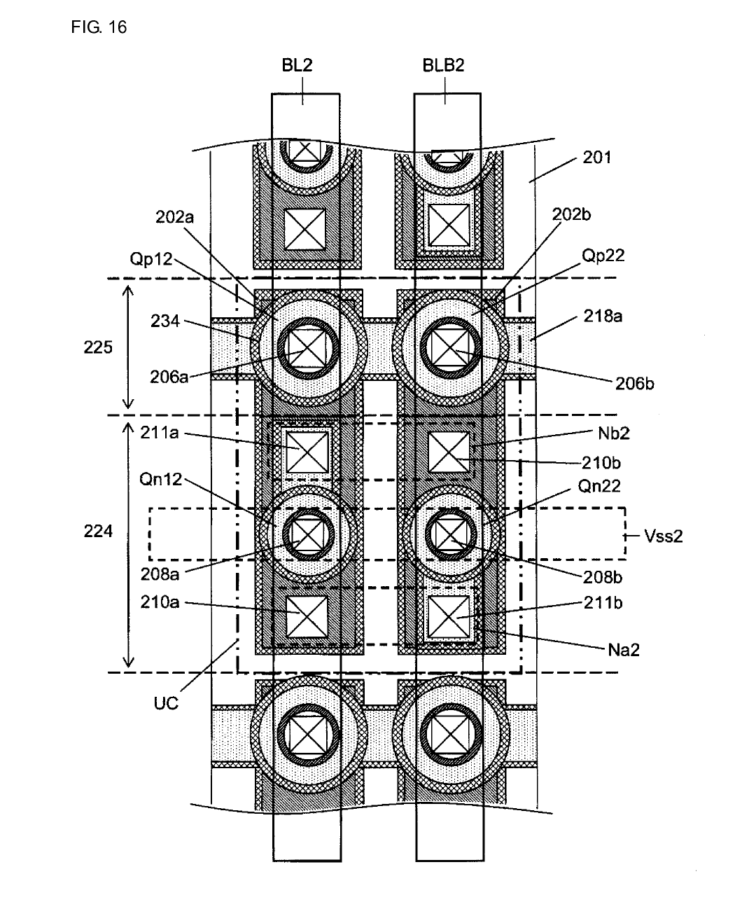

FIG. 16 illustrates an SRAM layout of this embodiment. In this embodiment, a point different from the first embodiment is the point that the shape of pillar-shaped silicon layers forming access transistors and the size of pillar-shaped silicon layers forming driver transistors are different. In the loadless 4T-SRAM of the present invention, it is necessary to set the leak current of the access transistors to be higher than the leak current of the driver transistors. As means for increasing the leak current of the access transistors, as illustrated in FIG. 16, the peripheral length of the pillar-shaped silicon layers forming the access transistors may be set to be greater than the peripheral length of the pillar-shaped silicon layers forming the driver transistors, thereby increasing the leak current.

In contrast, to improve the read out margin, the peripheral length of the pillar-shaped silicon layers of the driver transistors may be formed to be greater than the peripheral length of the pillar-shaped silicon layers forming the access transistors, thereby increasing the current of the driver transistors. Accordingly, the read out margin can be improved.

In this embodiment, the same pillar layout as that in the first embodiment is used by way of example. Actually, however, the layout is not limited to that of the first embodiment, and this embodiment is similarly applicable to layouts of other embodiments.

The other points are the same as those in the configuration discussed in the first embodiment, and hence, description thereof is omitted.

### Third Embodiment

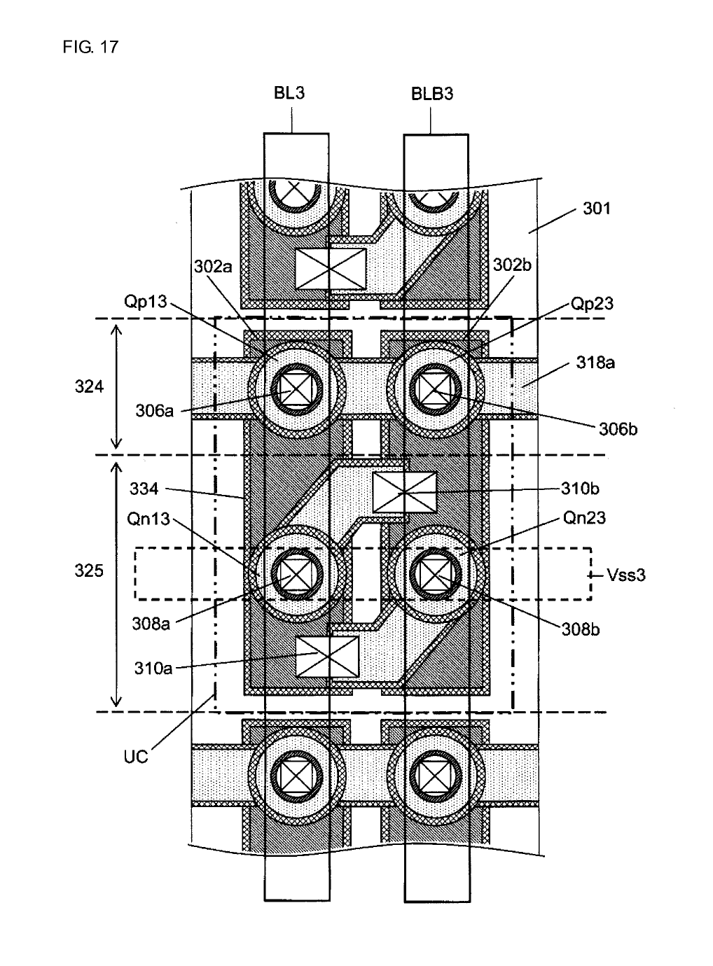

FIG. 17 illustrates an SRAM cell layout of this embodiment. This embodiment is different from the first embodiment in the following points. Qa3, which is a storage node formed of the first diffusion layers on the substrate, and a gate line extending from a gate electrode of a driver transistor Qn23 are connected by a common contact 310a formed over the storage node Qa3 and the gate line. Qb3, which is a storage node formed of the second diffusion layers on the substrate, and a gate line extending from a gate electrode of a driver transistor Qn13 are connected by a common contact 310b formed over the storage node Qb3 and the gate line. The number of contacts in the SRAM cell can be reduced by directly connecting a gate and a storage node by a contact, instead of a wiring layer, as described above. The cell area can be reduced by adjusting the arrangement of the pillar-shaped silicon layers and the contacts.

As an example of the hierarchical wiring configuration, it is possible to realize a configuration in which Vss3 is formed of a lower layer line and bit lines (BL3 and BLB3) are formed of upper layer lines. Note that, in this embodiment, the node connection line Na1 and the node connection line Nb1 are formed of contacts.

In this embodiment, the same pillar layout as that in the first embodiment is used by way of example. Actually, however, the layout is not limited to that of the first embodiment, and this embodiment is similarly applicable to other layouts.

The other points are the same as those in the configuration discussed in the first embodiment, and hence, description thereof is omitted.

### Fourth Embodiment

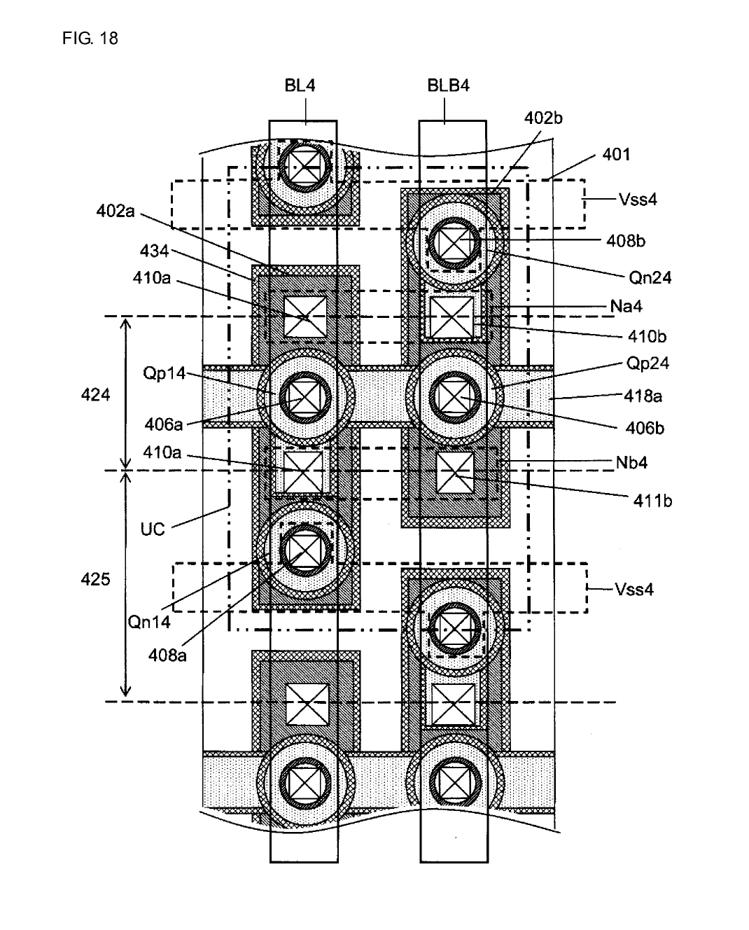

FIG. 18 illustrates an SRAM cell layout of this embodiment. This embodiment is different from the first embodiment in the following points. In the first embodiment, on the storage node Qa1, the contact 110a is arranged adjacent only to the driver transistor Qn11. However, on the storage node Qb1, the contact 110b is arranged on a diffusion layer between the driver transistor Qn21 and the access transistor Qp21. This layout asymmetry may generate asymmetry in characteristics of the SRAM cells, and the operation margin may become narrower. In this embodiment, the layout of an access transistor Qp14, contacts (410a and 411a), and a driver transistor Qn14 on a first storage node Qa4 is symmetrical to the layout of an access transistor Qp24, contacts (410b and 411b), and a driver transistor Qn24 on a second storage node Qb4. Therefore, there is no deterioration of the operation margin caused by the above-described asymmetry, and SRAM cells with a wide operation margin can be configured.

As an example of the hierarchical wiring configuration, it is possible to realize a configuration in which a node connection line Na4, a node connection line Nb4, and a ground potential line Vss4 are formed of lower layer lines, and bit lines (BL1 and BLB1) are formed of upper layer lines.

### Fifth Embodiment

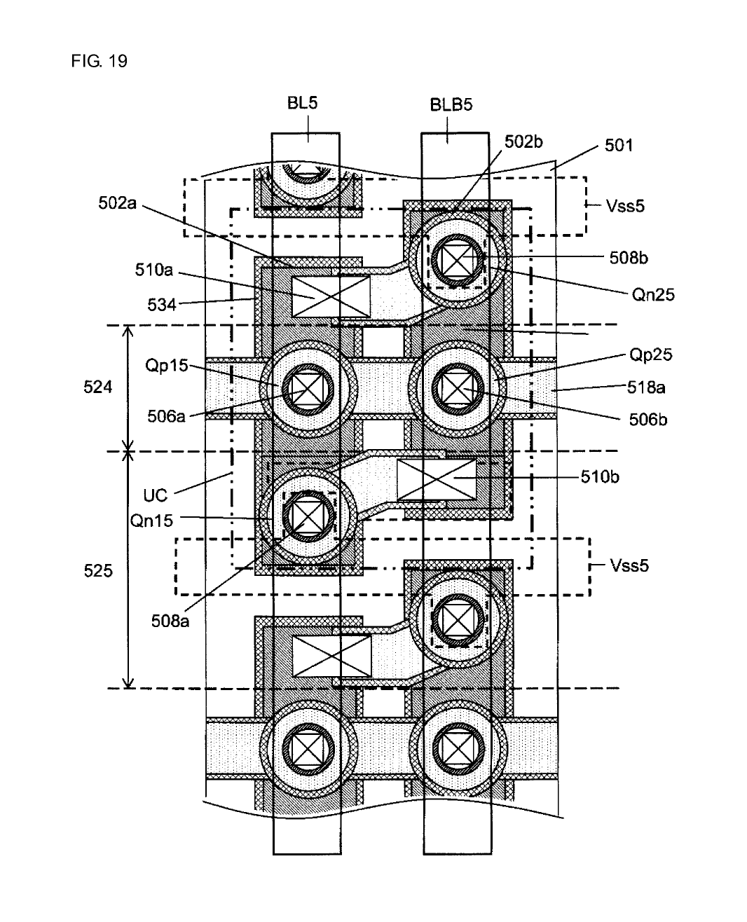

FIG. 19 illustrates an SRAM cell layout of this embodiment.

This embodiment has symmetrical layouts, like the fourth embodiment. Therefore, SRAM cells with a wide operation margin can be configured.

Also, like the second embodiment, Qa5, which is a storage node formed of the first diffusion layers on the substrate, and a gate line extending from a gate electrode of a driver transistor Qn25 are connected by a common contact 510a formed over the storage node Qa5 and the gate line. Qb5, which is a storage node formed of the second diffusion layers on the substrate, and a gate line extending from a gate electrode of a driver transistor Qn15 are connected by a common contact 510b formed over the storage node Qb5 and the gate line.

Note that, to share the wiring with other memory cells, the wiring of bit lines and the wiring of the ground potential are preferably arranged at a layer higher than the node connection lines, which are the wiring in each memory cell. In this embodiment, node connection lines are formed of contacts.

As an example of the hierarchical wiring configuration, it is possible to realize a configuration in which Vss3 is formed of a lower layer line and bit lines (BL5 and BLB5) are formed of upper layer lines. Note that, in this embodiment, a node connection line Na5 and a node connection line Nb5 are formed of contacts.

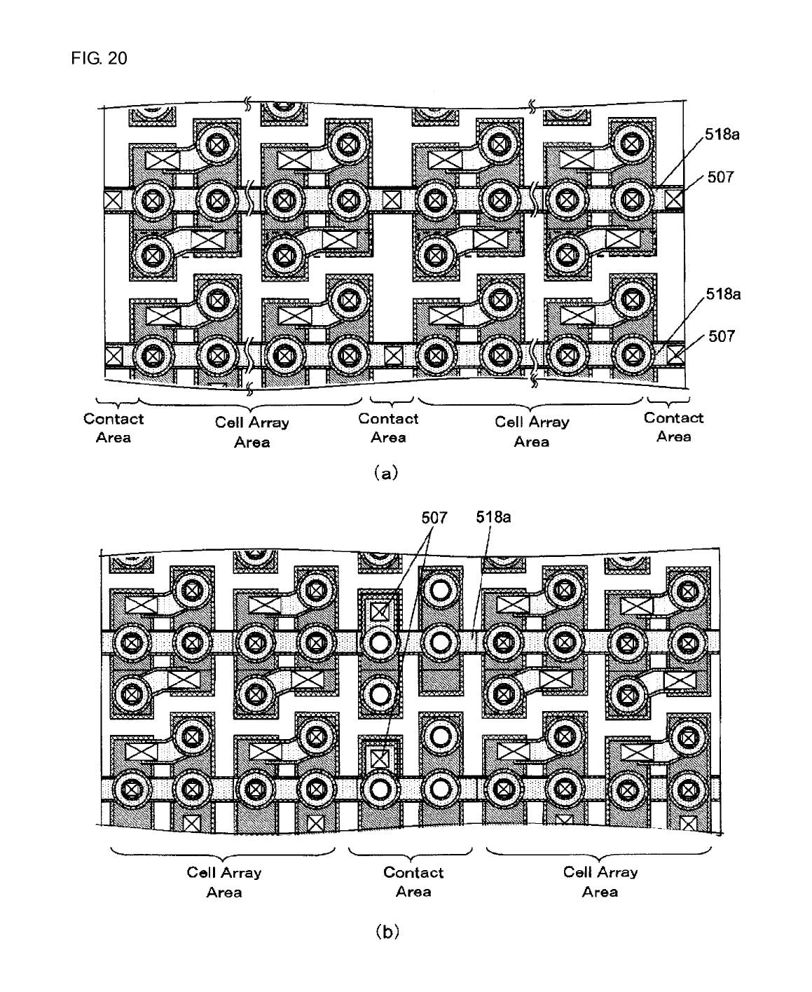

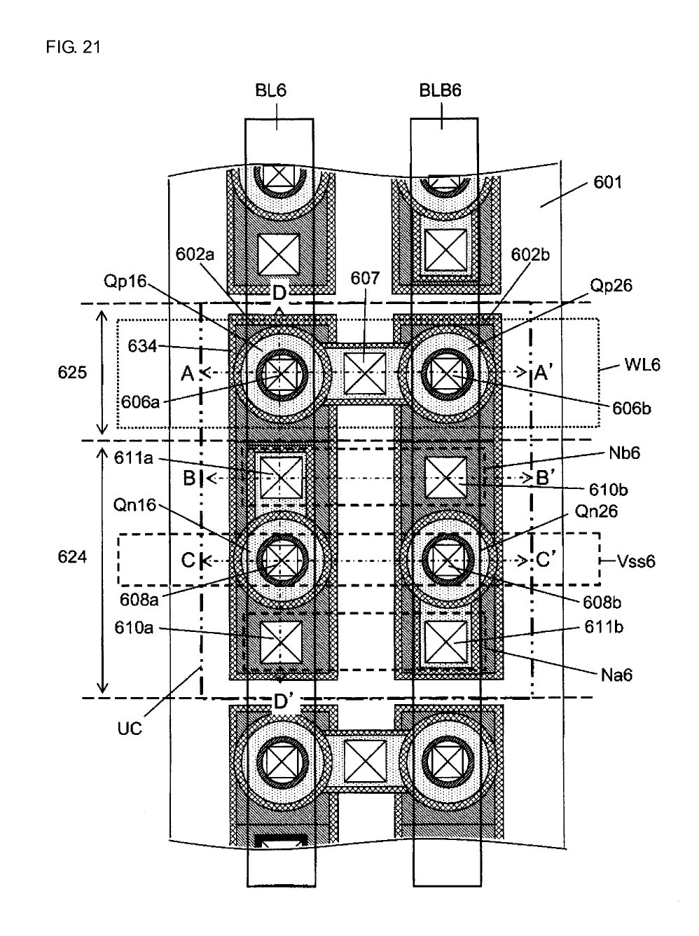

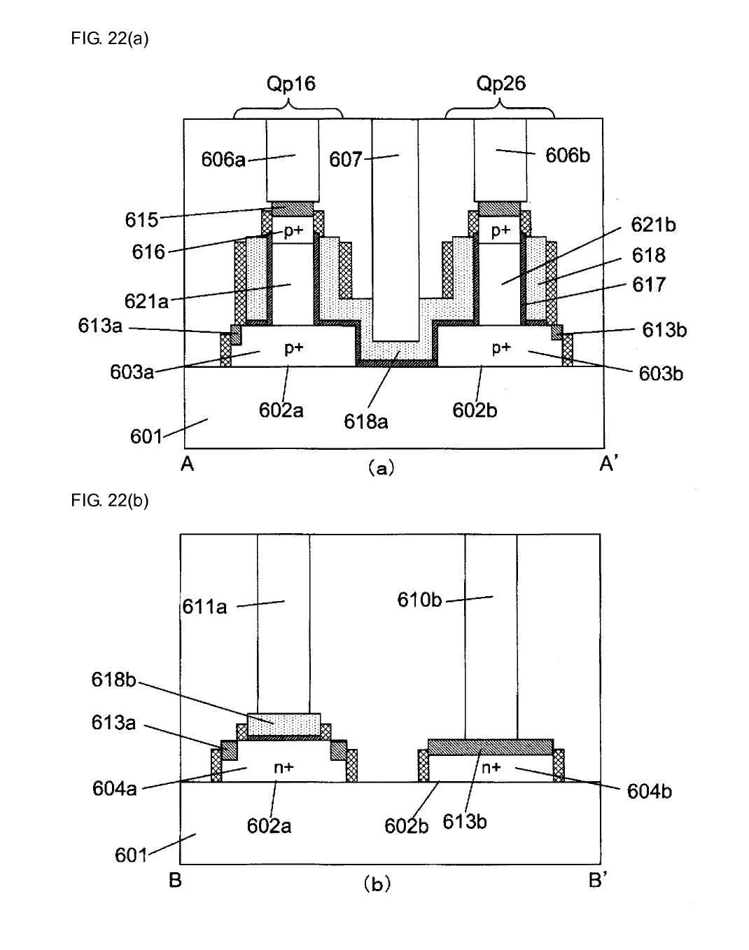

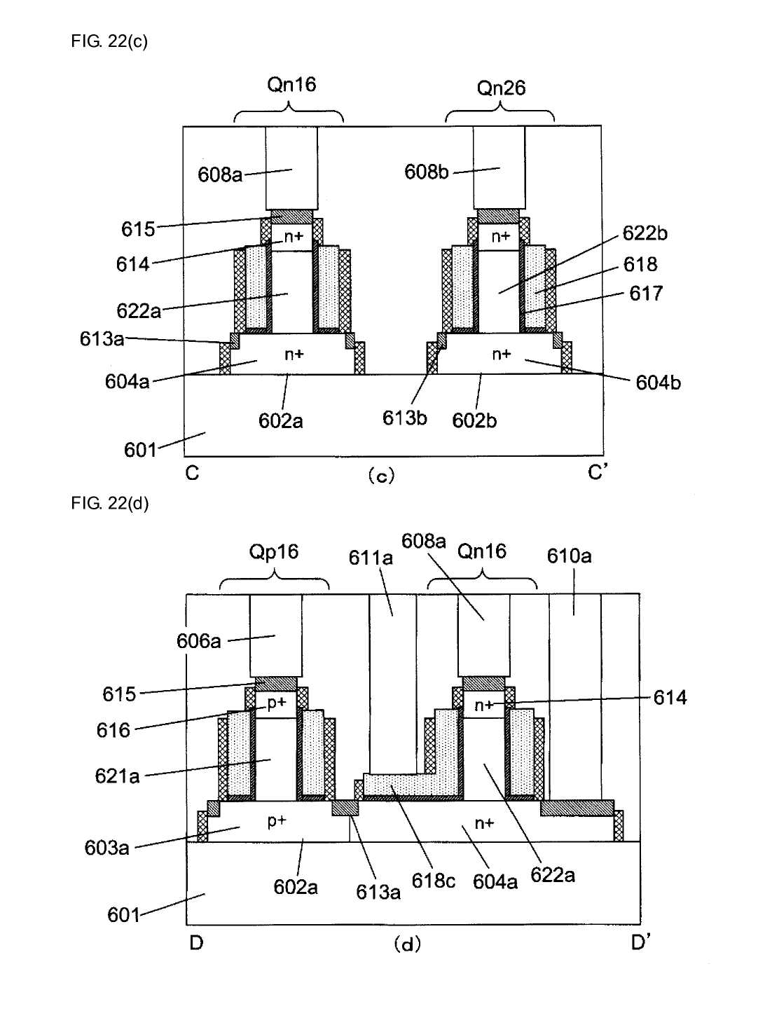

FIG. 20(a) is a plan view of a portion of an SRAM memory cell array including a plurality of SRAM memory cells.

In a cell array area in the diagram, a plurality of memory cells is arranged in the horizontal direction, and a word line 518a is shared among the plurality of memory cells arranged in the horizontal direction. The word line is connected to wiring at an upper layer by a contact 507 formed in a contact area and, as necessary, backed by a wiring layer. Therefore, unlike the SRAM cells in PTL 2, it is unnecessary to form, in each cell, a contact for the word line. Thus, the SRAM cell area can be reduced.

By connecting a plurality of cells to the word line 518a, there may be a problem of reading or writing delay due to delay of a signal on the word line at a cell distant from the word line contact 507. Therefore, the number of cells connected to the word line may be determined within the range where there is no problem of reading or writing delay.

FIG. 20(b) is a plan view of a portion of the SRAM cell array including a plurality of SRAM cells in another case. Similarly, in a cell array area in the diagram, a plurality of memory cells is arranged in the horizontal direction, and the word line 518a is shared among the plurality of memory cells arranged in the horizontal direction. However, in FIG. 20(b), as in the cell array area, pillars are arranged also in a contact area. By arranging pillars also in the contact area as above, errors between characteristics of SGTs adjacent to the contact area and characteristics of SGTs not adjacent to the contact area can be suppressed to the minimum.

As has been described above, according to the present invention, in a static memory cell constituted using four MOS transistors, the MOS transistors are SGTs in which the drains, gates, and sources are arranged in the vertical direction. The gates of access transistors serve as a word line that is shared among a plurality of cells adjacent to one another in a line (in the horizontal direction in the diagram). A contact for the word line is formed for a group of cells. Accordingly, a CMOS-type loadless 4T-SRAM with a very small memory cell area can be realized.

### REFERENCE SIGNS LIST

101, 201, 301, 401, 501: embedded oxide films

102, 102a, 102b, 202a, 202b, 302a, 302b, 402a, 402b, W502a, 502b, 602a, 602b: silicon layers

103, 103a, 103b, 203a, 203b, 603a, 603b: p+ diffusion layers

104a, 104b, 204a, 204b, 604a, 604b: n+ diffusion layers

106, 106a, 206a, 306a, 406a, 506a, 106b, 206b, 306b, 406b, 506b: contacts on access transistor pillar-shaped silicon layers

107: word line contact

108a, 208a, 308a, 408a, 508a, 108b, 208b, 308b, 408b, 508b: contacts on driver transistor pillar-shaped silicon layers

110a, 210a, 310a, 410a, 110b, 210b, 310b, 410b: contacts on storage nodes

111a, 211a, 111b, 211b: contacts on gate lines

113, 113a, 113b, 115, 513a, 513b, 515: silicide layers

114, 514: N+ diffusion layers on the top of pillars

116, 516: P+ diffusion layers on the top of pillars

117, 517: gate insulating films

118, 518: gate electrodes

118a, 118b, 118c, 518a, 518b, 518c: gate lines

118a, 218a, 318a, 418a: word lines

119: mask layer such as silicon oxide film

120: silicon layer

121, 121a, 121b, 521a, 521b: access transistor pillar-shaped silicon layers

122a, 122b, 522a, 522b: driver transistor pillar-shaped silicon layers

124, 524: P+ implanting areas

125, 525: N+ implanting areas

131: silicon oxide film

132: silicon nitride film sidewall

133: resist

134: silicon nitride film

Qp11, Qp21, Qp12, Qp22, Qp13, Qp23, Qp14, Qp24, Qp15, Qp25: access transistors

Qn11, Qn21, Qn12, Qn22, Qn13, Qn23, Qn14, Qn24, Qn15, Qn25: driver transistors

BL1, BL3, BL4, BL5, BLB1, BLB3, BLB4, BLB5: bit lines

Vss1, Vss2, Vss3, Vss4, Vss5: ground potential lines

Na1, Nb1, Na2, Nb2, Na5, Nb5: node connection lines

1. A semiconductor memory device comprising a plurality of static memory cells, each of which includes four MOS transistors arranged on an insulating film formed on a substrate,
wherein the four MOS transistor
function as a first and a second PMOS access transistors and a first and a second NMOS driver transistors, respectively, the first and second PMOS access transistors for supplying an electric charge in order to maintain data in a memory cell and accessing the memory, the first and second NMOS driver transistors for driving storage nodes in order to write and read data to and from the memory cell,
wherein, in the first and second PMOS access transistors,
a P-conductivity-type first diffusion layer, a first pillar-shaped semiconductor layer, and a P-conductivity-type second diffusion layer are arranged in a hierarchical manner in a vertical direction on the insulating film formed on the substrate, the first pillar-shaped semiconductor layer is arranged between the first diffusion layer formed at the bottom of the first pillar-shaped semiconductor layer and the second diffusion layer formed on the top of the first pillar-shaped semiconductor layer, and a gate insulating film and a gate are formed on a sidewall of the first pillar-shaped semiconductor layer,
and wherein, in the first and second NMOS driver transistors,
an N-conductivity-type third diffusion layer, a second pillar-shaped semiconductor layer, and an N-conductivity-type fourth diffusion layer are arranged in a hierarchical manner in the vertical direction on the insulating film formed on the substrate, the second pillar-shaped semiconductor layer is arranged between the third diffusion layer formed at the bottom of the second pillar-shaped semiconductor layer and the fourth diffusion layer formed on the top of the first pillar-shaped semiconductor layer, and a gate insulating film and a gate are formed on a sidewall of the second pillar-shaped semiconductor layer;
wherein the first PMOS access transistor and the first NMOS driver transistor are arranged adjacent to each other,
wherein the second PMOS access transistor and the second NMOS driver transistor are arranged adjacent to each other,
wherein the P-conductivity-type first diffusion layer formed at the bottom of the first PMOS access transistor and the N-conductivity-type third diffusion layer formed at the bottom of the first NMOS driver transistor, which function as a first storage node for maintaining data, are arranged on the insulating film,
wherein the first diffusion layer and the third diffusion layer functioning as the first storage node are connected to each other,
wherein the P-conductivity-type first diffusion layer formed at the bottom of the second PMOS access transistor and the N-conductivity-type third diffusion layer formed at the bottom of the second NMOS driver transistor, which function as a second storage node for maintaining data, are arranged on the insulating film,
wherein the first diffusion layer and the third diffusion layer functioning as the second storage node are connected to each other,
wherein gates of the first and second PMOS driver transistors are connected to each other by a first gate line, and the first gate line forms a word line by connecting to gates of the first and second PMOS access transistors in a plurality of memory cells adjacent to one another, and
wherein, for each group of memory cells adjacent to one another, a first contact is formed on the first gate line serving as the word line.

2. The semiconductor memory device according to claim 1, wherein, as in a memory cell area, pillars are arranged in an area in which the first contact is formed on the first gate line serving as the word line.

3. The semiconductor memory device according to claim 1,
wherein a second gate line extending from the gate of the first NMOS driver transistor is connected to the diffusion layers functioning as the second storage node by a second contact, and
wherein a third gate line extending from the gate of the second NMOS driver transistor is connected to the diffusion layers functioning as the first storage node by a third contact.

4. The semiconductor memory device according to claim 1,
wherein a peripheral length of sidewalls of the pillar-shaped semiconductor layers forming the first and second NMOS driver transistors is longer than or equal to a peripheral length of sidewalls of the pillar-shaped semiconductor layers forming the first and second PMOS access transistors, or
wherein the peripheral length of the sidewalls of the pillar-shaped semiconductor layers forming the first and second NMOS driver transistors is shorter than or equal to the peripheral length of the sidewalls of the pillar-shaped semiconductor layers forming the first and second PMOS access transistors.

5. The semiconductor memory device according to claim 1,
wherein the four MOS transistors are arranged in two rows and two columns on the insulating film,
wherein the first PMOS access transistor is arranged at a first column of a first row,
wherein the first NMOS driver transistor is arranged at a first column of a second row,
wherein the second PMOS access transistor is arranged at a second column of the first row, and
wherein the second NMOS driver transistor is arranged at a second column of the second row.

6. The semiconductor memory device according to claim 1,
wherein the four MOS transistors are arranged on the insulating film,
wherein the first PMOS access transistor and the second PMOS access transistor are arranged adjacent to each other,
wherein, in one direction orthogonal to a direction in which the first PMOS access transistor and the second PMOS access transistor are arranged adjacent to each other, the first NMOS driver transistor is arranged adjacent to the first PMOS access transistor, and
wherein, in the other direction orthogonal to the direction in which the first PMOS access transistor and the second PMOS access transistor are arranged adjacent to each other, the second NMOS driver transistor is arranged adjacent to the second PMOS access transistor.
